(19) United States
(12) Patent Application Publication
(10) Pub. No.: US 2017/0018431 A1
(43) Pub. Date: Jan. 19, 2017

(54) SEMICONDUCTOR MANUFACTURING APPARATUS AND MANUFACTURING METHOD OF SEMICONDUCTOR DEVICE

(71) Applicant: Kabushiki Kaisha Toshiba, Minato-ku (JP)

(72) Inventors: Toshiyuki MORITA, Yokkaichi (JP); Hiroshi TOYODA, Yokkaichi (JP)

(73) Assignee: Kabushiki Kaisha Toshiba, Minato-ku (JP)

(21) Appl. No.: 15/043,045

(22) Filed: Feb. 12, 2016

Related U.S. Application Data
(60) Provisional application No. 62/191,816, filed on Jul. 13, 2015.

(51) Int. Cl. H01L 21/288; C25D 7/12; C25D 17/06; H01L 21/768; C25D 21/10; H01L 21/67; H01L 21/687; C25D 3/38; C25D 21/02

(52) U.S. Cl. CPC H01L 21/288; C25D 3/38; C25D 7/12; C25D 17/06; C25D 21/02; C25D 21/10; H01L 21/67103; H01L 21/68714; H01L 21/76879

(57) ABSTRACT

A semiconductor manufacturing apparatus according to an embodiment includes a container that stores a processing liquid for plating processing of a substrate. A holder can hold the substrate. A cooler cools the substrate to a temperature lower than a temperature of the processing liquid before the holder immerses the substrate in the processing liquid in the container.

### CROSS REFERENCE TO RELATED APPLICATIONS

This application is based upon and claims the benefit of priority from the prior U.S. Provisional Patent Application No. 62/191,816, filed on Jul. 13, 2015, the entire contents of which are incorporated herein by reference.

### FIELD

The embodiments of the present invention relate to a semiconductor manufacturing apparatus and a manufacturing method of a semiconductor device.

### BACKGROUND

A damascene method is used to form fine wires in a semiconductor manufacturing process. By the damascene method, fine line-and-space patterns are formed on the surface of a substrate and then the space patterns are plated with a metallic material using a plating apparatus. The plated metallic material is polished, whereby wires embedded in the space patterns are formed.

However, wires and intervals between the wires have been increasingly downscaled in recent years and the line-and-space patterns have also been downscaled correspondingly. When a metallic material is to be embedded in quite narrow space patterns by a plating method, voids are likely to occur in the metallic material (wires) in the space patterns. The voids increase wire resistance or lead to poor connection of wires.

### BRIEF DESCRIPTION OF THE DRAWINGS

FIG. 1 is a schematic diagram showing an example of a configuration of a plating apparatus 1 according to a first embodiment;

FIG. 2 shows an example of a configuration of the plating apparatus 1 according to the first embodiment;

FIGS. 3A to 3D are schematic diagrams showing an example of operations of the plating apparatus 1 according to the first embodiment;

FIG. 4 is a graph showing a relation between the temperature of the plating solution P and the void occurrence rate;

FIG. 5 is a graph showing a relation between the temperature of the plating solution P and the limiting current value;

FIG. 6 shows an example of a configuration of a plating apparatus 12 according to a second embodiment;

FIG. 7A to 7D are schematic diagrams showing an example of operations of the plating apparatus 12 according to the second embodiment;

FIG. 8 shows an example of a configuration of the plating apparatus 12 according to a modification of the second embodiment;

FIG. 9 shows an example of a configuration of a plating apparatus 13 according to a third embodiment; and

FIGS. 10A to 10D are schematic diagrams showing an example of operations of the plating apparatus 13 according to the third embodiment.

### DETAILED DESCRIPTION

Embodiments will now be explained with reference to the accompanying drawings. The present invention is not limited to the embodiments.

A semiconductor manufacturing apparatus according to an embodiment includes a container that stores a processing liquid for plating processing of a substrate. A holder can hold the substrate. A cooler cools the substrate to a temperature lower than a temperature of the processing liquid before the holder immerses the substrate in the processing liquid in the container.

### First Embodiment

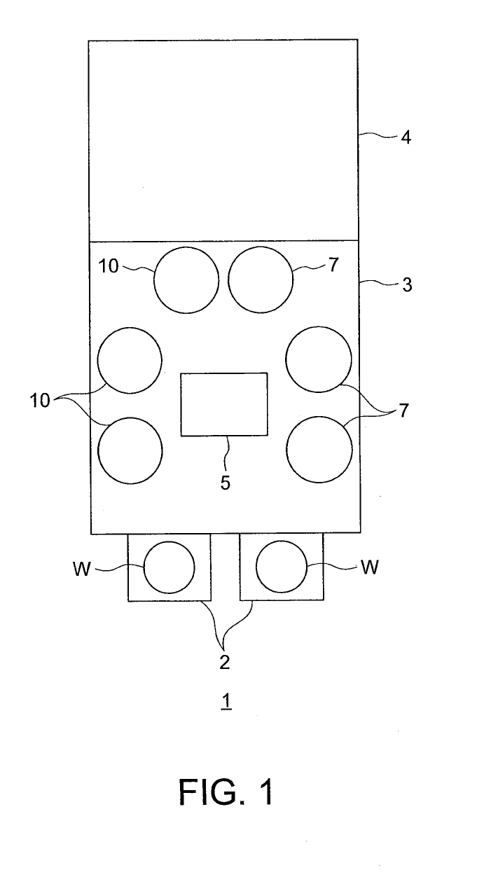

FIG. 1 is a schematic diagram showing an example of a configuration of a plating apparatus 1 according to a first embodiment. The plating apparatus 1 includes a load port 2, a processing part 3, and a plating-solution containing part 4. A substrate container that contains semiconductor substrates W can be attached to or detached from the load port 2 to enable the semiconductor substrates W to be delivered between the substrate container and the processing part 3.

The processing part 3 includes a delivery robot 5, plating tanks 10, and water rinse parts 7. The delivery robot 5 delivers semiconductor substrates W from the load port 2 to the plating tanks 10 when the semiconductor substrates W are subjected to plating processing, or delivers semiconductor substrates W from the plating tanks 10 to the water rinse parts 7 after end of plating processing and further delivers the semiconductor substrates W from the water rinse parts 7 to the load port 2. The plating tanks 10 house the semiconductor substrates W therein to expose the surfaces of the semiconductor substrates W to a plating solution and perform plating processing. The plating solution circulates between the plating tanks 10 and the plating-solution containing part 4. The water rinse parts 7 are provided to rinse away the plating solution from the semiconductor substrates W after the plating processing is performed to the semiconductor substrates W. The plating-solution containing part 4 contains the plating solution and supplies a new plating solution to the plating tanks 10 or recovers a plating solution used in the plating tanks 10.

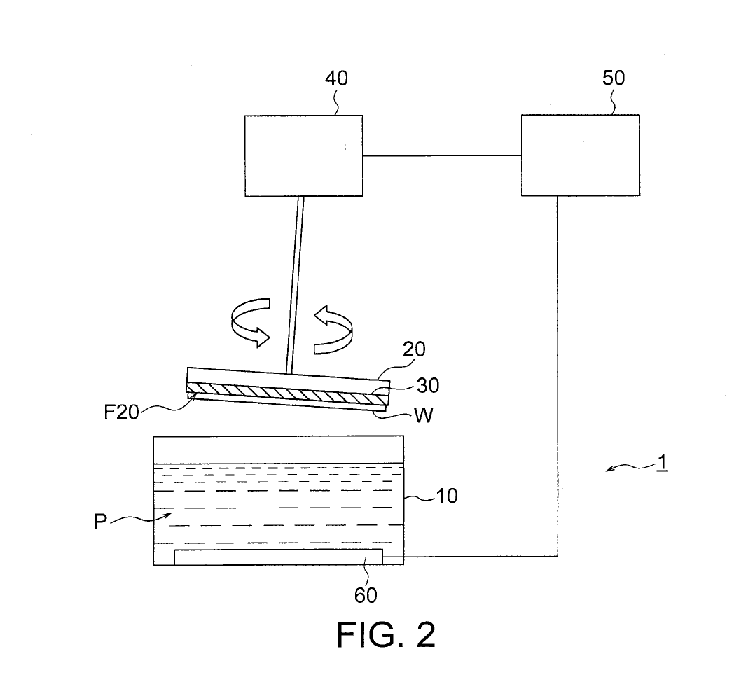

FIG. 2 shows an example of a configuration of the plating apparatus 1 according to the first embodiment. The plating apparatus 1 includes the plating tank 10, a holder 20, a cooler 30, a driver 40, a controller 50, and an electrode 60.

The plating tank 10 as a container has a plating solution P stored therein to perform plating processing of a semiconductor substrate W. The plating solution P in the plating tank 10 is circulated between the plating tank 10 and the plating-solution containing part 4 as described above. For example, when a semiconductor substrate W is to be plated with copper, a copper sulfate plating solution (also VMS (Virgin Make-up Solution)) and an additive (an accelerator, a suppressor, a lever, or the like) are used as the plating solution P.

The holder 20 is capable of having a semiconductor substrate W mounted thereon and rotating the semiconductor substrate W. The holder 20 holds the semiconductor substrate W in such a manner that the semiconductor substrate W does not fall even when a mount face F20 on which the semiconductor substrate W is mounted is caused to face in a direction toward the plating solution P (in a downward direction).

The cooler 30 is provided inside the holder 20 and can cool the semiconductor substrate W mounted on the holder 20. The cooler 30 can be, for example, a Peltier device. In this case, the Peltier device is placed in the holder 20 to cause the endothermic face to face toward the semiconductor substrate W.

The driver 40 can move the holder 20 upward or downward with respect to the plating solution P while rotating the holder 20. Accordingly, the driver 40 can immerse the surface of the semiconductor substrate W mounted on the holder 20 in the plating solution P. The driver 40 also can cause the mount face F20 of the holder 20 to face upward (in the opposite direction to the plating solution P) or downward (in a direction toward the plating solution P). When the semiconductor substrate W is to be mounted on the mount face F20 of the holder 20 or when the semiconductor substrate W is to be detached from the mount face F20 of the holder 20, the driver 40 causes the mount face F20 of the holder 20 to face upward. When the semiconductor substrate W is to be immersed in the plating solution P, the driver 40 causes the mount face F of the holder 20 to face downward.

The controller 50 controls the constituent elements of the plating apparatus 1 such as the driver 40. For example, the controller 50 controls the driver 40 to change the rotation, height, or orientation of the holder 20. The controller 50 supplies power between the electrode 60 and the holder 20 to perform plating processing of the semiconductor substrate W. The controller 50 also adjusts power to the cooler 30 to control the temperature of the cooler 30. For example, in the present embodiment, the controller 50 causes the cooler 30 to cool the semiconductor substrate W in advance and stops the cooling operation of the cooler 30 after the semiconductor substrate W is immersed in the plating solution P. Accordingly, the time of film formation by the plating processing can be shortened and also occurrence of voids in a plated material can be suppressed. The cooling operation will be explained in detail later.

The electrode 60 is provided in the plating solution P and applies a voltage from the controller 50 to the plating solution P. For example, the electrode 60 functions as an anode and the holder 20 functions as a cathode. The plating apparatus 1 can form a film of a plating material (copper, for example) on the surface of the semiconductor substrate W by application of a voltage difference between the electrode 60 and the holder 20 to the plating solution P and the semiconductor substrate W.

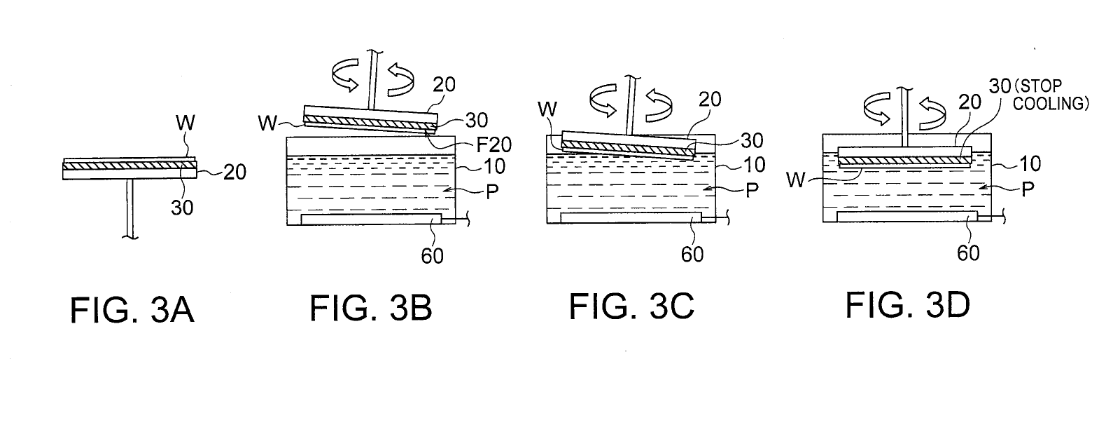

FIGS. 3A to 3D are schematic diagrams showing an example of operations of the plating apparatus 1 according to the first embodiment. In FIGS. 3A to 3D, illustrations of the driver 40 and the controller 50 are omitted.

In the present embodiment, the surface of the semiconductor substrate W has an interlayer dielectric film having line-and-space patterns formed thereon to form fine wires. The width of grooves (concave portions) in the line-and-space patterns is, for example, about 5 nanometers and the depth of the grooves is, for example, about 7.5 nanometers. A barrier metal layer (titanium, for example) and a seed layer (copper, for example) are formed in advance on the surface of the interlayer dielectric film by a sputtering method. The barrier metal layer and the seed layer are formed not only on the top surfaces of convex portions of the interlayer dielectric film but also on the inner walls (the bottom surfaces and the side surfaces) of the concave portions. In the plating processing, the seed layer becomes a seed for a plating material (copper, for example) and encourages film formation of the plating material.

First, as shown in FIG. 3A, a semiconductor substrate W is mounted on the holder 20. As described above, the semiconductor substrate W includes a barrier metal layer and a seed layer on the interlayer dielectric film having line-and-space patterns. During mounting of the semiconductor substrate W, the holder 20 faces upward (in the opposite direction to the plating solution P). Before the holder 20 immerses the semiconductor substrate W in the plating solution P in the plating tank 10, the cooler 30 cools the semiconductor substrate W to a temperature lower than the temperature of the plating solution P.

The plating tank 10 is managed to a temperature higher than about 21° C., for example, to about 25° C. (the ordinary temperature) and the cooler 30 cools the semiconductor substrate W to about 17° C. or lower.

Next, as shown in FIG. 3B, the holder 20 rotates while causing the surface F20 to face downward (in a direction toward the plating solution P). Accordingly, the surface of the semiconductor substrate W also faces toward the plating solution P and rotates.

Subsequently, as shown in FIG. 3C, the holder 20 moves the semiconductor substrate W downward to the plating solution P while rotating the semiconductor substrate W and immerses the semiconductor substrate W in the plating solution P. In order to prevent bubbles from remaining on the surface of the semiconductor substrate W when the semiconductor substrate W is immersed in the plating solution P, the holder 20 immerses the semiconductor substrate W in the plating solution P in a state where the surface of the semiconductor substrate W is slightly inclined with respect to the liquid level of the plating solution P. As described above, the plating solution P is, for example, a chemical obtained by adding an additive to a copper sulfate plating solution (VMS).

Next, as shown in FIG. 3D, the cooler 30 has cooled the semiconductor substrate W in advance and keeps the cooling operation for a predetermined time after the semiconductor substrate W is immersed. After the predetermined time has passed from immersion of the semiconductor substrate W, the cooler 30 stops cooling the semiconductor substrate W. Accordingly, the surface temperature of the semiconductor substrate W is kept lower than the temperature of the plating solution P for the predetermined time (several seconds, for example) after the semiconductor substrate W is immersed in the plating solution P. Because cooling of the semiconductor substrate W is thereafter stopped, the surface temperature of the semiconductor substrate W approaches the temperature of the plating solution P and becomes substantially equal to that of the plating solution P.

As described above, in the present embodiment, the cooler 30 performs the cooling operation at the initial time of immersion of the semiconductor substrate W to set the temperature of the semiconductor substrate W to be lower than that of the plating solution P and thereafter the cooler 30 stops to set the temperature of the semiconductor substrate W to be substantially equal to that of the plating solution P. The reason why this cooling operation is performed and effects thereof are explained below.

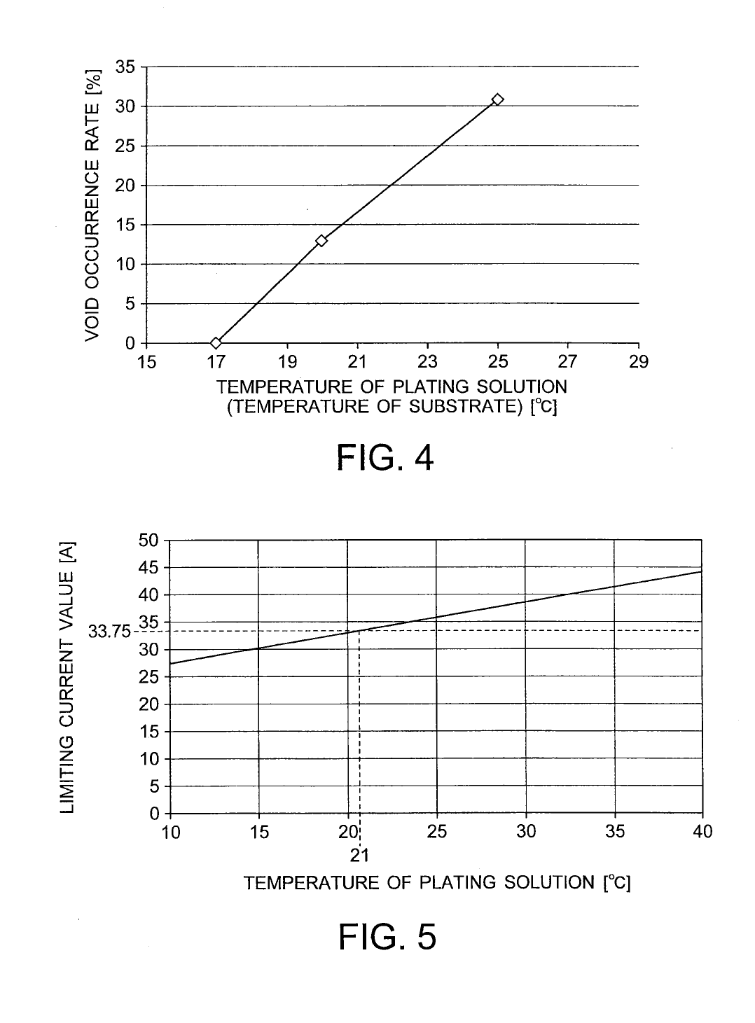

FIG. 4 is a graph showing a relation between the temperature of the plating solution P and the void occurrence rate. The horizontal axis represents the temperature of the plating solution P and the vertical axis represents the void occurrence rate. The temperature in a clean room in which the plating processing is performed is kept at, for example, about 25° C. (the ordinary temperature or the room temperature).

As the temperature of the plating solution P is lower, the void occurrence rate is lower. For example, when the temperature of the plating solution P was relatively high and was, for example, about 25° C. (the ordinary temperature or the room temperature), the void occurrence rate was about 31%. When the temperature of the plating solution P was, for example, about 20° C., the void occurrence rate was about 13%. When the temperature of the plating solution P was, for example, about 17° C., the void occurrence rate was about 0%. As described above, when the temperature of the plating solution P is set to be lower, the void occurrence rate becomes lower. When the temperature of the plating solution P is relatively high, the plating solution P adversely dissolves the seed layer (copper, for example). If the seed layer is dissolved before a plating material is embedded in the space portions, voids occur in the plating material (the wire material) after plating processing. When the temperature of the plating solution P is relatively low, the plating solution P does not dissolve the seed layer so much. Therefore, voids are less likely to occur in the plating material. By setting the temperature of the plating solution P at about 17° C. or lower, the void occurrence rate can be set to be substantially 0%.

The maximum current value (the limiting current value) that is allowed to flow in the plating solution P becomes lower when the temperature of the plating solution P is set to be lower. The limiting current value is the maximum current value that is allowed to flow in the plating solution P between the holder 20 and the electrode 60. When the limiting current value is lowered, the film formation rate in the plating processing is adversely limited. When the film formation rate is lowered, this leads to prolongation of the film formation time (the plating processing time) in the plating processing and degrades the productivity. For example, FIG. 5 is a graph showing a relation between the temperature of the plating solution P and the limiting current value. This graph shows that the limiting current value lowers when the temperature of the plating solution P lowers. It is assumed, for example, that the controller 50 causes current of about 33.75 amperes to flow between the holder 20 and the electrode 60 at the time of film formation (accumulation or additional plating) of a plating material after the plating material is embedded in the space portions. Because the limiting current value is about 33.75 amperes when the temperature of the plating solution P is about 21° C., the controller 50 needs to set the current between the holder 20 and the electrode 60 to be lower than about 33.75 amperes at the time of accumulation or additional plating when the temperature of the plating solution P becomes lower than about 21° C. This leads to reduction of the film formation rate and prolongation of the film formation time (the plating processing time). In the graph of FIG. 5, the VMS concentration of the plating solution P is about 30 grams/liter.

In order to lower the temperature of the plating solution P itself in the plating tank 10, a cooling apparatus (a chiller) that cools the plating tank 10 is required. Because current is caused to flow in the plating solution P in the plating processing, the temperature of the plating solution P is likely to increase due to Joule heat. A powerful cooling apparatus is needed to keep the temperature of the plating solution P at a low temperature even when the plating processing is repeatedly performed. In this case, the cost of the plating apparatus 1 and the processing cost of the semiconductor substrate W are increased.

Therefore, in the present embodiment, the cooler 30 is provided in the holder 20 to cool the semiconductor substrate W. The cooler 30 cools the semiconductor substrate W at a temperature lower than that of the plating solution P before the semiconductor substrate W is immersed in the plating solution P. After the semiconductor substrate W is then immersed in the plating solution P, the cooler 30 stops cooling the semiconductor substrate W. Accordingly, part of the plating solution P located near the surface of the semiconductor substrate W is initially cooled by the cooler 30, the holder 20, and the semiconductor substrate W. At this time, the temperature of the part of the plating solution P near the surface of the semiconductor substrate W becomes substantially equal to the cooling temperature of the cooler 30, the holder 20, and the semiconductor substrate W. On the other hand, after a predetermined time has passed from immersion of the semiconductor substrate W in the plating solution P, the cooler 30 is stopped. The temperature of the part of the plating solution P near the surface of the semiconductor substrate W thereby returns to the temperature of the other part of the plating solution P in the plating tank 10.

For example, it is assumed that the temperature of the plating solution P is set at a temperature (the room temperature (about 25° C.), for example) higher than about 17° C. to shorten the plating processing time. Meanwhile, the cooler 30 cools the temperature of the semiconductor substrate W to be equal to or lower than about 17° C. In this case, when the semiconductor substrate W is immersed in the plating solution P, the temperature of part of the plating solution P near the surface of the semiconductor substrate W is lowered to be near about 17° C. by the cooler 30, the holder 20, and the semiconductor substrate W. Accordingly, the temperature of the part of the plating solution P near the surface of the semiconductor substrate W at the start of the plating processing of the semiconductor substrate W is lower than that of the other part of the plating solution P in the plating tank 10. That is, the plating processing is started with the plating solution P having a relatively low temperature. As a result, the seed layer already formed on the semiconductor substrate W is less likely to be dissolved and the occurrence rate of voids in the wire material embedded in the concave portions (the space portions) becomes low.

On the other hand, the cooler 30 stops cooling the semiconductor substrate W after a predetermined time has passed from immersion of the semiconductor substrate W in the plating solution P. The temperature of the part of the plating solution P near the surface of the semiconductor substrate W thereby returns to the temperature (about 25° C., for example) of the other part of the plating solution P in the plating tank 10. Accordingly, the temperature of the part of the plating solution P near the surface of the semiconductor substrate W increases and the limiting current value that is allowed to flow in the plating solution P increases. Therefore, the film formation rate of the plating material increases and the film formation time (the plating time) in the plating processing is shortened. As a result, degradation of the productivity can be suppressed.

It suffices that the cooler 30 stops cooling the semiconductor substrate W at a point of time when the plating material is embedded in the space portions (the groove portions) of the line-and-space patterns. This can more reliably suppress occurrence of voids in wires within the space portions. The point of time when the plating material is embedded in the space portions can be determined based on experiments or the past history. For example, while depending also on the aspect ratio of the space portions, the time in which the plating material is embedded in the fine space portions is several seconds after the semiconductor substrate W is immersed in the plating solution P to start the plating processing. Therefore, it suffices that the cooler 30 stops cooling the semiconductor substrate W several seconds after the semiconductor substrate W is immersed in the plating solution P. The plating processing (accumulation or additional plating) is thereafter performed with the plating solution P having a relatively high temperature. This increases the film formation rate (the accumulation rate or rate of the additional plating).

Thereafter, the plating apparatus 1 pulls the semiconductor substrate W out of the plating solution P and the plating solution P adhering to the semiconductor substrate W is rinsed away in the water rinse part 7 in FIG. 1. Subsequently, the semiconductor substrate W is housed in the substrate container in the load port 2 and then the plating processing ends.

As described above, the plating apparatus 1 according to the present embodiment cools the semiconductor substrate W to a temperature (equal to or lower than about 17° C., for example) lower than the temperature (equal to or higher than about 21° C., for example) of the plating solution P before the semiconductor substrate W is immersed in the plating solution P, and stops cooling after the semiconductor substrate W is immersed in the plating solution P. Accordingly, occurrence of voids in the wire material can be suppressed and also the film formation rate of the plating material can be increased to suppress prolongation of the film formation time after the wire material is embedded in the space portions.

The cooler 30 is provided not in the plating tank 10 but in the holder 20 and cools the semiconductor substrate W. This configuration can lower the void occurrence rate without changing the temperature of the entire plating solution P in the plating tank 10. That is, there is no need to provide a powerful cooling apparatus in the plating tank 10 and it suffices to control the temperature of the plating solution P to be constant (about 25° C., for example). Accordingly, increase in the cost of the plating apparatus 1 and the processing cost of the semiconductor substrate W can be suppressed.

### Second Embodiment

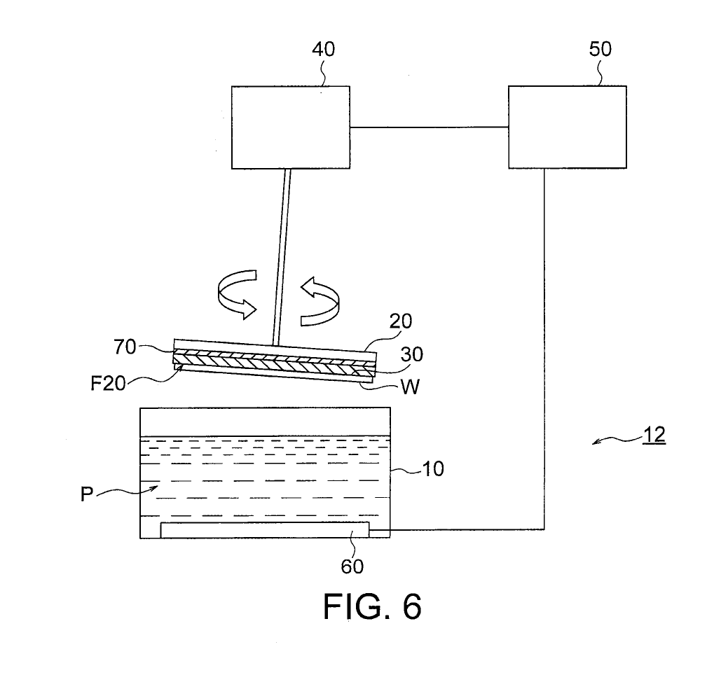

FIG. 6 shows an example of a configuration of a plating apparatus 12 according to a second embodiment. The plating apparatus 12 further includes a heater 70. The heater 70 is provided in the holder 20 to heat the semiconductor substrate W. The controller 50 adjusts power to the heater 70 to control the temperature of the heater 70 as well as that of the cooler 30. Accordingly, after the semiconductor substrate W is immersed in the plating solution P, the cooler 30 stops cooling the semiconductor substrate W and the heater 70 heats the semiconductor substrate W. Because both the cooler 30 and the heater 70 are thus provided in the second embodiment, control on the temperature of the semiconductor substrate W is facilitated. Other configurations of the second embodiment can be identical to corresponding configurations of the first embodiment.

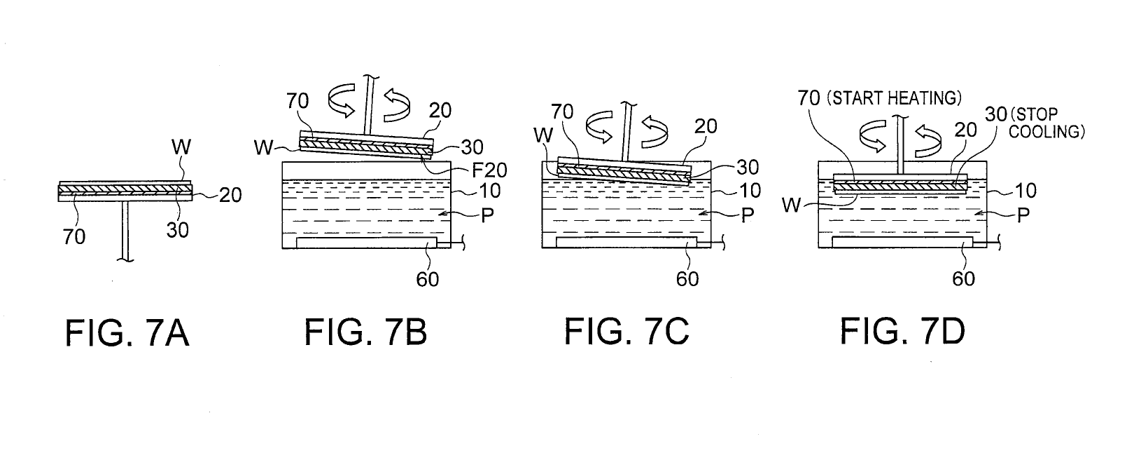

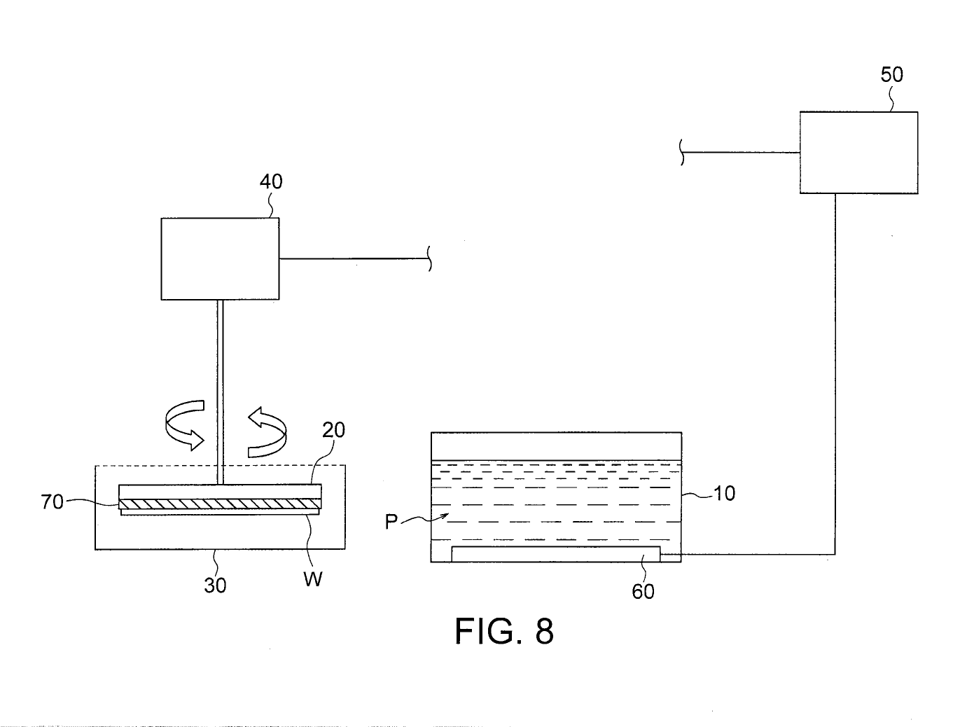

FIG. 7A to 7D are schematic diagrams showing an example of operations of the plating apparatus 12 according to the second embodiment. The operations shown in FIGS. 7A to 7C can be identical to those explained with reference to FIGS. 3A to 3C. During these operations, the heater 70 is stopped without performing a heating operation.

Next, as shown in FIG. 7D, the cooler 30 stops cooling the semiconductor substrate W after the semiconductor substrate W is immersed. Meanwhile, the heater 70 starts the heating operation for the semiconductor substrate W after the cooling operation of the cooler 30 is stopped. The heater 70 heats the semiconductor substrate W to a predetermined temperature (a temperature equal to or higher than about 21° C., for example). Accordingly, the surface temperature of the semiconductor substrate W is kept lower than the temperature of the plating solution P for a certain time period (several seconds, for example) after the semiconductor substrate W is immersed in the plating solution P. Thereafter, cooling of the semiconductor substrate W is stopped and conversely the heater 70 heats the semiconductor substrate W, so that the surface temperature of the semiconductor substrate W approaches the temperature of the plating solution P. For example, the heater 70 can cause the surface temperature of the semiconductor substrate W to be substantially equal to that of the plating solution P by heating the semiconductor substrate W.

Because the cooler 30 and the heater 70 are both provided according to the second embodiment, the heater 70 can increase the temperature of the semiconductor substrate W after cooling of the semiconductor substrate W is stopped. The plating apparatus 12 can thereby increase the temperature of the semiconductor substrate W to be substantially equal to that of the plating solution P quickly after cooling of the semiconductor substrate W is stopped.

Furthermore, the plating apparatus 12 according to the second embodiment cools the semiconductor substrate W before the semiconductor substrate W is immersed in the plating solution P similarly in the first embodiment. Therefore, the second embodiment can also achieve effects identical to those of the first embodiment.

### (Modification)

FIG. 8 shows an example of a configuration of the plating apparatus 1 or 12 according to a modification of the first or second embodiment. In the first or second embodiment described above, the cooler 30 is provided in the holder 20. However, the cooler 30 can be provided separately from the holder 20 and cool the semiconductor substrate W until just before the semiconductor substrate W is immersed in the plating solution P. For example, as shown in FIG. 8, the semiconductor substrate W is housed in the cooler 30 in the shape of a box and cooled in a state of being mounted on the holder 20. The cooler 30 cools the semiconductor substrate W to a temperature (equal to or lower than about 17° C., for example) lower than the temperature of the plating solution P. The cooler 30 can cool the semiconductor substrate W by means of any of gas, liquid, and solid media. At this time, the driver 40 can rotate the semiconductor substrate W together with the holder 20 to suppress variation in the temperature of the semiconductor substrate W.

Thereafter, the plating apparatus 1 or 12 pulls the holder 20 and the semiconductor substrate W out of the cooler 30 and immerses the holder 20 and the semiconductor substrate W in the plating solution P in the plating tank 10. At this time, the holder 20 and the semiconductor substrate W have a temperature lower than that of the plating solution P. After the semiconductor substrate W is immersed in the plating solution P, the temperature of the semiconductor substrate W becomes substantially equal to that of the plating solution P by heat exchange between the semiconductor substrate W (the holder 20) and the plating solution P or by the heating operation of the heater 70. Accordingly, even when the cooler 30 is provided outside the holder 20, effects identical to those of the first or second embodiment can be achieved.

### Third Embodiment

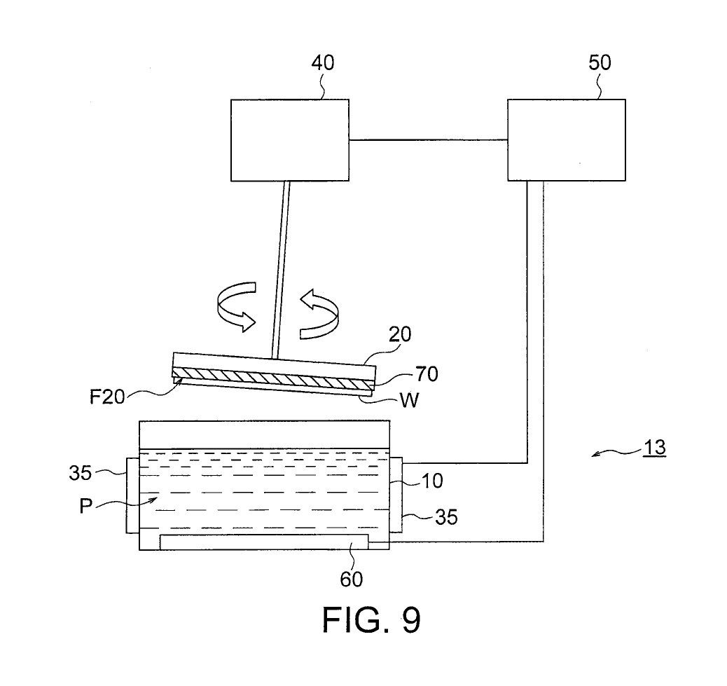

FIG. 9 shows an example of a configuration of a plating apparatus 13 according to a third embodiment. In the third embodiment, the cooler 30 is not provided in the holder 20. However, a cooler 35 is provided in the plating tank 10. The heater 70 is provided in the holder 20 similarly in the second embodiment.

The cooler 35 is provided to cool the plating solution P in the plating tank 10. The controller 50 adjusts power to the cooler 35 to control the temperature of the plating solution P. For example, the cooler 35 cools the plating solution P to a temperature (equal to or lower than about 17° C., for example) lower than the room temperature (about 25° C.). Accordingly, when the semiconductor substrate W is immersed in the plating solution P to start plating processing, the temperature of the plating solution P near the surface of the semiconductor substrate W is relatively low. After a predetermined time has passed from immersion of the semiconductor substrate W in the plating solution P to start the plating processing, the heater 70 heats the semiconductor substrate W. For example, the heater 70 heats the semiconductor substrate W to the room temperature. This can increase the temperature of the plating solution P near the surface of the semiconductor substrate W. Other configurations of the third embodiment can be identical to corresponding configurations of the first or second embodiment.

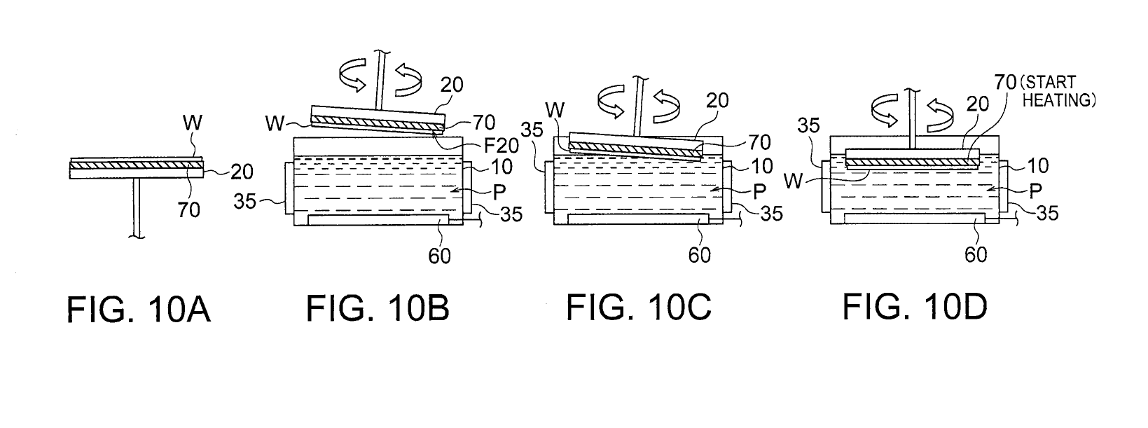

FIGS. 10A to 10D are schematic diagrams showing an example of operations of the plating apparatus 13 according to the third embodiment. In FIGS. 10A to 10D, the cooler 35 cools the plating solution P to keep the temperature of the plating solution P at a predetermined temperature (a temperature equal to or lower than 17° C., for example). On the other hand, the heater 70 starts the heating operation for the semiconductor substrate W after the semiconductor substrate W is immersed in the plating solution P as shown in FIG. 10D. For example, the heater 70 heats the semiconductor substrate W to a predetermined temperature (a temperature equal to or higher than about 21° C., for example) after the semiconductor substrate W is immersed in the plating solution P and the plating material is embedded in the space portions. In this manner, the surface temperature of the semiconductor substrate W is kept at a temperature substantially equal to that of the plating solution P for a predetermined time period (several seconds, for example) after the semiconductor substrate W is immersed in the plating solution P. Because the heater 70 thereafter heats the semiconductor substrate W, the temperature of the plating solution P near the surface of the semiconductor substrate W is increased by heat of the heater 70, the holder 20, and the semiconductor substrate W to become a temperature substantially equal to the room temperature. Other operations of the third embodiment can be identical to corresponding operations of the first or second embodiment.

According to the third embodiment, the semiconductor substrate W is immersed in the previously-cooled plating solution P. At this time, the heater 70 does not perform the heating operation. Therefore, the semiconductor substrate W comes to have a temperature substantially equal to that of the plating solution P at the initial time of immersion. Occurrence of voids is thereby suppressed while the plating material is embedded in the space portions. When the plating material is embedded in the space portions after immersion of the semiconductor substrate W, the heater 70 starts the heating operation and increases the temperature of the semiconductor substrate W. Because the temperature of part of the plating solution P near the surface of the semiconductor substrate W is accordingly increased, the film formation rate of the plating material is increased correspondingly. As described above, the plating apparatus 13 according to the third embodiment cools the plating solution P in advance and increases the temperature of the semiconductor substrate W after immersion. Even with this configuration, effects identical to those of the first or second embodiment can be achieved.

In the third embodiment, the cooler 35 keeps the temperature of the plating solution P to a predetermined temperature (a temperature equal to or lower than about 17° C., for example) when the heater 70 heats the semiconductor substrate W. However, the cooler 35 can alternatively stop the cooling operation when the heater 70 heats the semiconductor substrate W. This configuration does not lose the effects of the third embodiment. Furthermore, by stopping the cooling operation for the plating solution P, the temperature of plating solution P is increased more easily. In addition, stopping of the cooling operation also leads to reduction in power consumption.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor manufacturing apparatus comprising:
a container storing a processing liquid for plating processing of a substrate;
a holder capable of holding the substrate; and
a cooler cooling the substrate to a temperature lower than a temperature of the processing liquid before the holder immerses the substrate in the processing liquid in the container.

2. The apparatus of claim 1, wherein the cooler stops cooling the substrate after the substrate is immersed in the processing liquid in the container.

3. The apparatus of claim 1, wherein the cooler cools the substrate to 17° C. or lower.

4. The apparatus of claim 2, wherein the cooler cools the substrate to 17° C. or lower.

5. The apparatus of claim 1, further comprising a heater heating the substrate after the substrate is immersed in the processing liquid in the container.

6. The apparatus of claim 2, further comprising a heater heating the substrate after the substrate is immersed in the processing liquid in the container.

7. The apparatus of claim 3, further comprising a heater heating the substrate after the substrate is immersed in the processing liquid in the container.

8. The apparatus of claim 2, further comprising a heater heating the substrate after the substrate is immersed in the processing liquid in the container and the cooler stops cooling the substrate.

9. The apparatus of claim 3, further comprising a heater heating the substrate after the substrate is immersed in the processing liquid in the container and the cooler stops cooling the substrate.

10. A semiconductor manufacturing apparatus comprising:
a container storing a processing liquid for plating processing of a substrate;
a holder capable of holding the substrate;
a cooler cooling the processing liquid; and
a heater heating the substrate after the substrate is immersed in the processing liquid in the container.

11. The apparatus of claim 10, wherein the cooler stops cooling the processing liquid in the container when the heater heats the substrate.

12. The apparatus of claim 10, wherein the cooler cools the substrate to 17° C. or lower.

13. The apparatus of claim 11, wherein the cooler cools the substrate to 17° C. or lower.

14. A manufacturing method of a semiconductor device using a semiconductor manufacturing apparatus comprising a container storing a processing liquid for plating processing of a substrate, a holder capable of holding the substrate, and a cooler cooling the substrate or the processing liquid, the method comprising:
cooling the substrate or the processing liquid; and
immersing the substrate in the processing liquid in the container.

15. The method of claim 14, wherein the cooler stops cooling the substrate or the processing liquid after the substrate is immersed in the processing liquid in the container.

16. The method of claim 14, wherein the cooler cools the substrate or the processing liquid to 17° C. or lower.

17. The method of claim 14, wherein
the semiconductor manufacturing apparatus further comprises a heater heating the substrate, and
the method further comprises heating the substrate after the substrate is immersed in the processing liquid in the container.

18. The method of claim 15, wherein
the semiconductor manufacturing apparatus further comprising a heater heating the substrate, and
the method further comprises heating the substrate after the substrate is immersed in the processing liquid in the container and the cooler stops cooling the substrate.

19. The method of claim 14, wherein the processing liquid comprises a copper sulfate plating solution (VMS (Virgin Make-up Solution) plating the substrate with copper.
